(19) United States
(12) Patent Application Publication
(10) Pub. No.: US 2021/0286218 A1
(43) Pub. Date: Sep. 16, 2021

(54) DISPLAY PANEL, MANUFACTURING METHOD, AND DISPLAY DEVICE

(71) Applicant: TCL China Star Optoelectronics Technology Co., Ltd., Shenzhen (CN)

(72) Inventor: Xiaoping YU, Shenzhen (CN)

(73) Assignee: TCL China Star Optoelectronics Technology Co., Ltd., Shenzhen (CN)

(21) Appl. No.: 16/625,770

(22) PCT Filed: Dec. 17, 2019
(86) PCT No.: PCT/CN2019/125940

§ 371 Date: Dec. 23, 2019

(30) Foreign Application Priority Data
Nov. 15, 2019 (CN) 201911117383.X

(51) Int. Cl. G02F 1/1362; G02F 1/1368; C09B 3/14; C09B 67/20; C08K 5/3437; C08K 3/04; C08K 13/02; G03F 7/09

(52) U.S. Cl. CPC G02F 1/136209; G02F 1/1368; C09B 3/14; C09B 67/0063; G02F 2202/04; C08K 3/04; C08K 13/02; G03F 7/091; C08K 5/3437

(57) ABSTRACT

The present invention discloses a display panel, a manufacturing method, and a display device, wherein the display panel includes: a color filter substrate; an array substrate disposed correspondingly to the color filter substrate and comprising two metal layers; and a liquid crystal layer sandwiched between the color filter substrate and the array substrate, wherein a reflection blocking layer is disposed on one of the metal layers near a viewer, to reduce a reflectance of the array substrate to ambient light. The present invention can improve display contrast, thus beneficial to improving a viewing experience of the viewer.

### BACKGROUND OF INVENTION

### Field of Invention

The present invention relates to the field of display technology, and in particular, to a display panel, a manufacturing method and a display device.

### Description of Prior Art

Contrast is one of important indicators to evaluate image quality performance of a liquid crystal display (LCD). In a real use scene, due to the influence of the surrounding ambient light, a reflectivity of the display panel will affect the contrast of the screen. As shown in the formula below, Lₒₙ, L_{off}, and R_{ambient} respectively indicate a bright state of the display panel, a dark state brightness of the display panel, and an ambient brightness, and RL represents a reflectivity of the display panel. One can increase the contrast of the display panel by two aspects: 1) increasing the bright state brightness Lon of the display panel, and 2) reducing the reflectivity RL of the display panel.

Contrast=(Lₒₙ+L_{ambient}*R_{L})/(L_{off}+L_{ambient}*R_{L})

In the prior art, metal reflection of a (thin-film transistor, TFT) area of a display panel (especially having a narrow bezel or no bezel) is strong, resulting in an increase in the reflectivity of the display panel to the ambient light, and a reduce in the image quality of the display panel.

Therefore, the prior art needs to be further improved.

### SUMMARY OF INVENTION

The present invention provides a display panel, a manufacturing method and a display device, which can solve the problem of poor display contrast caused by a strong reflection of the existing display panel to ambient light.

In order to solve the above technical problem, the present invention provides a display panel.

The display panel includes:

a color filter substrate;

an array substrate disposed correspondingly to the color filter substrate and including two metal layers; and

a liquid crystal layer sandwiched between the color filter substrate and the array substrate,

wherein a reflection blocking layer is disposed on one of the metal layers near a viewer, to reduce a reflectance of the array substrate to ambient light.

The array substrate includes:

a support substrate; and

a first metal layer, a first insulating layer, an active layer, and a second metal layer sequentially disposed on the support substrate,

wherein the reflection blocking layer is disposed between the support substrate and the first metal layer.

The reflection blocking layer is further disposed between the second metal layer and the active layer.

The display panel further includes:

a first intermediate layer disposed between the reflection blocking layer and the first metal layer to improve adhesion between the reflection blocking layer and the first metal layer; and

a second intermediate layer disposed between the reflection blocking layer and the second metal layer to improve adhesion between the reflection blocking layer and the second metal layer.

The array substrate includes:

a support substrate; and

a first metal layer, a first insulating layer, an active layer, and a second metal layer sequentially disposed on the support substrate,

wherein the reflection blocking layer is disposed on the second metal layer.

The reflection blocking layer is further disposed on the first metal layer.

The reflection blocking layer includes:

a resin and a dye, the dye including a perylene dimer dye or a mixture of the perylene dimer dye and carbon black,

wherein the perylene dimer has a structural formula as follows:

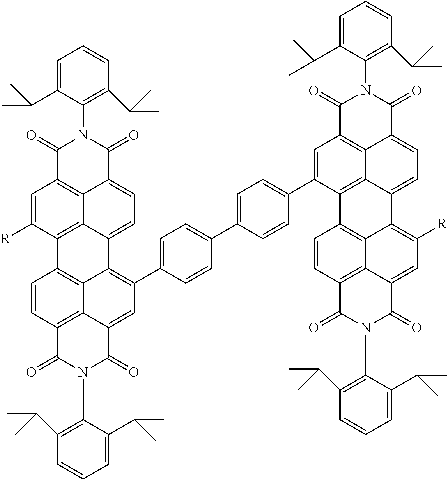

wherein R includes at least one of the following chemical structures:

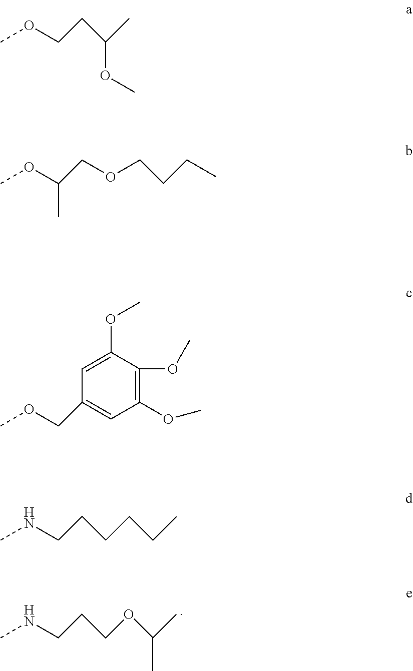

R includes at least one group of a and d, a and e, b and d, c and d, and c and e.

In order to solve the above technical problem, the present invention provides a method of manufacturing a display panel.

The methods include:

providing an array substrate, which includes two metal layers; and

disposing a reflection blocking layer on one of the metal layers near a viewer to reduce reflectance of the array substrate to ambient light.

In order to solve the above technical problem, the present invention provides display device, including the display panel.

Different from the prior art, the present application covers a metal layer that strongly reflects ambient light with a reflection blocking layer, which can effectively reduce a reflection of the metal layer to ambient light in a viewing angle of a viewer, thereby improving display contrast, thus beneficial to improving a viewing experience of the viewer.

### BRIEF DESCRIPTION OF DRAWINGS

FIG. 1 is a schematic structural diagram of a display panel according to a first embodiment of the present application.

FIG. 2 is a schematic structural diagram of a display panel according to a second embodiment of the present application.

FIG. 3 is a schematic structural view of a display panel according to a third embodiment of the present application.

FIG. 4 is a schematic structural diagram of a display panel according to a fourth embodiment of the present application.

FIG. 5 is a schematic structural diagram of a display panel according to a fifth embodiment of the present application.

FIG. 6 is a schematic structural diagram of a display panel according to a sixth embodiment of the present application.

FIG. 7 is a schematic structural diagram of a display device according to an embodiment of the present application.

FIG. 8 is a flowchart of a method of manufacturing a display panel according to an embodiment of the present application.

FIG. 9 is a flowchart of a method of manufacturing a display panel according to another embodiment of the present application.

### DETAILED DESCRIPTION OF PREFERRED EMBODIMENTS

Please refer to the figures in the drawings, in which, like numbers refer to like elements throughout the description of the figures. Hereinafter, the present invention will be described in further detail with reference to examples. It is to be understood, however, that these examples are for illustrative purposes only and are not intended to limit the scope of the present invention.

It should be noted that all directional indicators (such as up, down, left, right, front, back, etc.) in the embodiments of the present invention are only used to explain the relationship between components in a specific posture (as shown in the drawings). The relative positional relationship, movement situation, etc., if the specific posture changes, the directivity indication also changes accordingly.

In addition, the descriptions related to “first”, “second”, etc. in the present invention are only for descriptive purposes, and cannot be understood as indicating or implying their relative importance or implicitly indicating the number of technical features indicated. Therefore, the features defined as “first” and “second” may explicitly or implicitly include at least one of the features. In addition, the technical solutions between the various embodiments can be combined with each other, but must be based on those that can be realized by a person of ordinary skill in the art. When the combination of technical solutions conflicts or cannot be achieved, such a combination of technical solutions should be considered non-existent and not within the scope of protection claimed by the present invention.

Please refer to FIG. 1, which is a schematic structural diagram of a display panel according to a first embodiment of the present application. The display panel includes:

a color filter substrate 10, an array substrate 20 disposed correspondingly to the color filter substrate 10 and including two metal layers 21; and a liquid crystal layer 30 sandwiched between the color filter substrate 10 and the array substrate 20, wherein a reflection blocking layer 22 is disposed on one of the metal layers 21 near a viewer 40, to reduce a reflectance of the array substrate 20 to ambient light.

In this embodiment, the metal layers that strongly reflect ambient light are covered with the reflection blocking layer 22, which can effectively reduce a reflection of the metal layers 21 to ambient light in a viewing angle of a viewer, thereby improving display contrast, thus beneficial to improving a viewing experience of the viewer 40.

Specifically, in the display panel, a side of the color filter substrate 10 may face the viewer 40 (that is, the color filter substrate 10 faces outward, and ambient light is incident from the side of the color filter substrate 10), or a side of the array substrate 20 may face the viewer 40 (that is, the array substrate 20 faces outward, and ambient light is incident from the side of the array substrate 20). The reflection blocking layer 22 is black, which can reduce the reflection of ambient light by the metal layer 21. Further, the reflection blocking layer 22 may be disposed on both of the two metal layers 21, or may be disposed on only one of the metal layers according to whether the array substrate 20 faces the viewer 40. In order to further simplify the production process and reduce costs, the reflection blocking layer 22 is disposed on one of the metal layers facing the viewer 40.

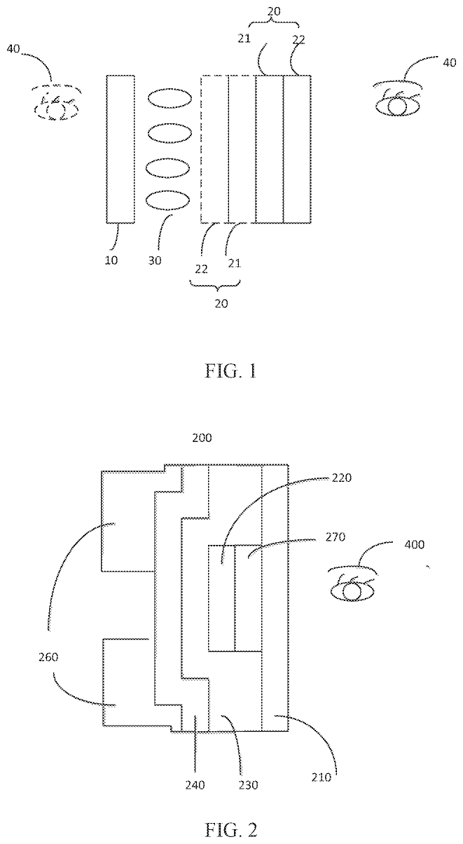

In an embodiment, please refer to FIG. 2. FIG. 2 is a schematic structural diagram of a display panel according to a second embodiment of the present application. In the case that the array substrate 200 faces the viewer 400, the array substrate 200 includes a support substrate 210; and a first metal layer 220, a first insulating layer 230, an active layer 240, and a second metal layer 260 sequentially disposed on the support substrate 210, wherein the reflection blocking layer 270 is disposed between the support substrate 210 and the first metal layer 220.

In this embodiment, the first metal layer 220 may be a gate layer; and the second metal layer 260 is a source/drain layer. The active layer may be a polysilicon layer, and the first insulating layer 230 may be made of an organic material or an inorganic material. When the insulating material is an inorganic material, it may be silicon nitride, silicon oxide, or a composite thereof. When the insulating material is made of an organic material, it may be a resin series insulating film, an acrylic series insulating film, or the like.

Since the array substrate 200 faces the viewer 400, the ambient light reflected by the first metal layer 220 has a greater impact on the viewing experience of the viewer 400, and therefore the reflection blocking layer 270 is disposed between the support substrate 210 and the first metal layer 220, and the reflection of ambient light by the first metal layer 220 can be effectively reduced, thereby effectively improving the viewing experience. Further, in order to obtain a better effect, a size of the reflection blocking layer 270 covers at least the first metal layer 220. Furthermore, in order to further reduce costs, the size of the reflection blocking layer 270 is just sufficient to cover the first metal layer 220 so that ambient light is substantially not reflected by the first metal layer 220.

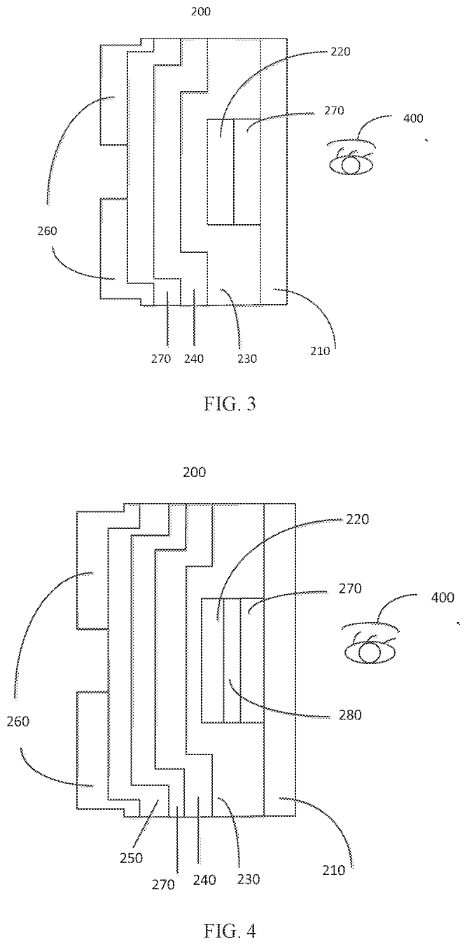

In another embodiment, please refer to FIG. 3. Unlike the embodiment in FIG. 2, the reflection blocking layer 270 of this embodiment is further disposed between the second metal layer 260 and the active layer 240, this embodiment blocks the reflected light at two positions, and a better display effect can be obtained.

Further, please refer to FIG. 4, which is a schematic structural diagram of a display panel according to a fourth embodiment of the present application. The display panel further includes a first intermediate layer 280 disposed between the reflection blocking layer 270 and the first metal layer 220 to improve an adhesion between the reflection blocking layer 270 and the first metal layer 220. Specifically, the first intermediate layer 280 may be made of silicon nitride and/or silicon oxide. Further, the display panel further includes a second intermediate layer 250 disposed between the reflection blocking layer 270 and the second metal layer 260 to improve the adhesion between the reflection blocking layer 270 and the second metal layer 260. Specifically, the second intermediate layer 250 may be made of silicon nitride and/or silicon oxide.

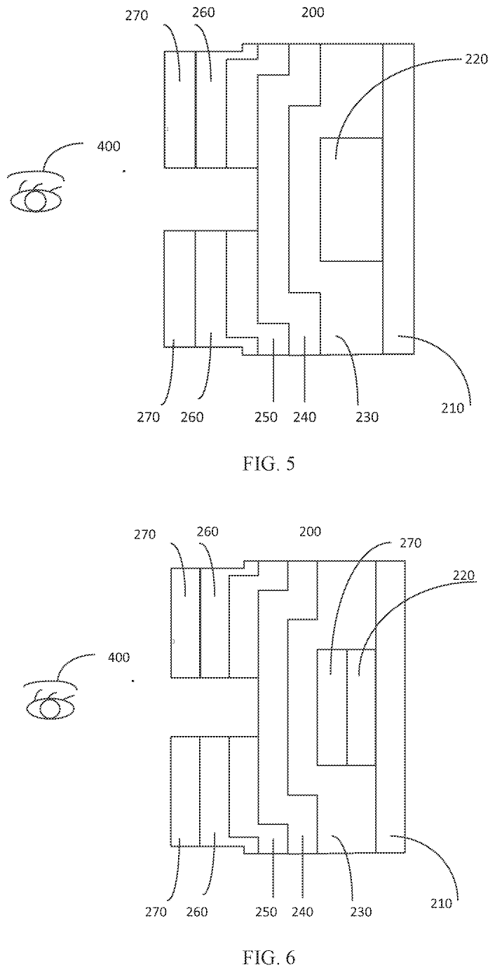

In another embodiment, please refer to FIG. 5. FIG. 5 is a schematic structural diagram of a display panel according to a fifth embodiment of the present application. The array substrate 200 is far from the viewer 400. In this case, the array substrate 200 includes: a support substrate 210; a first metal layer 220, a first insulating layer 230, an active layer 240, and a second metal layer 260 sequentially disposed on the supporting substrate 210; wherein the reflection blocking layer 270 is disposed on the second metal layer 260.

In this embodiment, if the array substrate 200 is far from the viewer 400, the ambient light reflected by the second metal layer 260 has a greater impact on the viewing experience of the viewer 400, and therefore the reflection blocking layer 270 is disposed on the second metal layer 260, such that the reflection of ambient light by the second metal layer 260 can be effectively reduced, thereby effectively improving the viewing experience. Further, in order to obtain a better effect, a size of the reflection blocking layer 270 covers at least the second metal layer 260. Furthermore, in order to further reduce costs, the size of the reflection blocking layer 270 is sufficient to just cover the second metal layer 260 so that ambient light is substantially not reflected by the second metal layer 260.

In another embodiment, please refer to FIG. 6. Unlike the embodiment in FIG. 5, the reflection blocking layer 270 of this embodiment is further disposed on the first metal layer 220, wherein specifically, the reflection blocking layer 270 is disposed between the first metal layer 220 and the first insulating layer 230. This embodiment blocks the reflected light at two positions, and a better display effect can be obtained.

Further, the display panel 200 further includes a passivation layer (not shown) disposed between the reflection blocking layer 270 and the second metal layer 260 to simplify the manufacturing process. In this embodiment, the passivation layer may improve a display effect and extend a service life of the display panel 200, and can be formed by coating or the like and made of an organic material or an inorganic material. When the material of the passivation material is an inorganic material, it may specifically be silicon nitride, silicon oxide, or a composite thereof. When the material of the passivation layer is an organic material, it may be a resin series insulating film, an acrylic series insulating film, or the like. Further, if the reflection blocking layer 270 is provided on the passivation layer, there is no need to provide a black matrix on the passivation layer (the reflection blocking layer 270 provided on the passivation layer plays the role of the black matrix), and all light-shading layers can be prepared in one photolithography process, which is beneficial to further simplifying the process and reduce costs.

Specifically, the reflection blocking layer 270 includes a resin and a dye, the dye including a perylene dimer dye or a mixture of the perylene dimer dye and carbon black,

wherein the perylene dimer has a structural formula as follows:

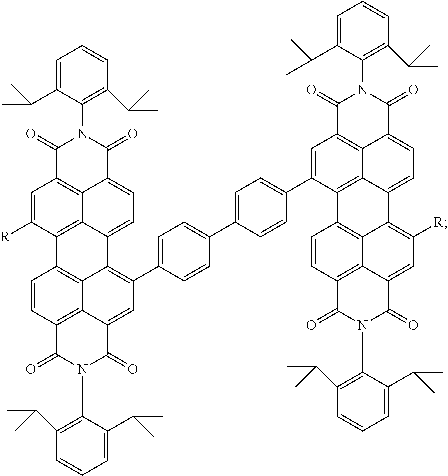

wherein R includes at least one of the following chemical structures:

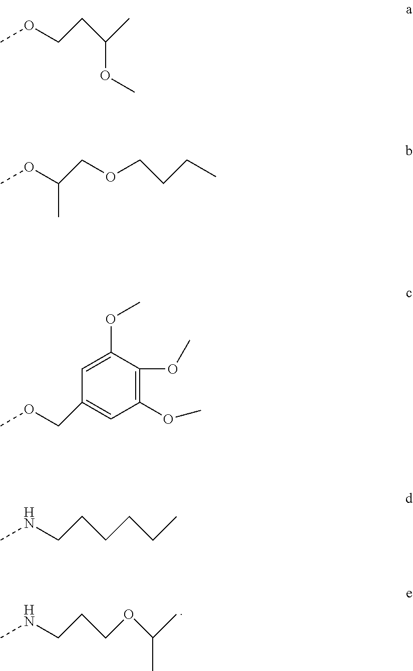

In this embodiment, the reflection blocking layer 270 is a black blocking layer, which can effectively reduce the reflection of ambient light by the metal layer. Specifically, the material of the reflection blocking layer 270 may be a black photoresist, which includes a resin and a dye. The resin must have thermal resistance to prevent the structure of the reflection blocking layer 270 from being damaged by high-temperature baking during the process of preparing the reflection blocking layer 270, thereby impacting a use effect. For example, the resin may be a polyimide resin. In order to simplify the process and obtain better results, the dye needs to have better solubility, thermal resistance, and absorbance properties in commonly used solvents (such as monomethyl ether propylene glycol acetate (PGMEA)). Correspondingly, the dye may be a perylene dimer dye or a mixture of the dye and carbon black, wherein the perylene dimer is excellent in thermal resistance and can withstand a temperature of 320 degrees Celsius. Furthermore, the two R in the structural formula of the perylene dimer may be the same or different in their structures. When the two R have different structures, they include at least one group of a and d, a and e, b and d, c and d, and c and e; and any combination of the above can further improve the effect of the reflection blocking layer.

In order to solve the above technical problems, the present invention provides a display device.

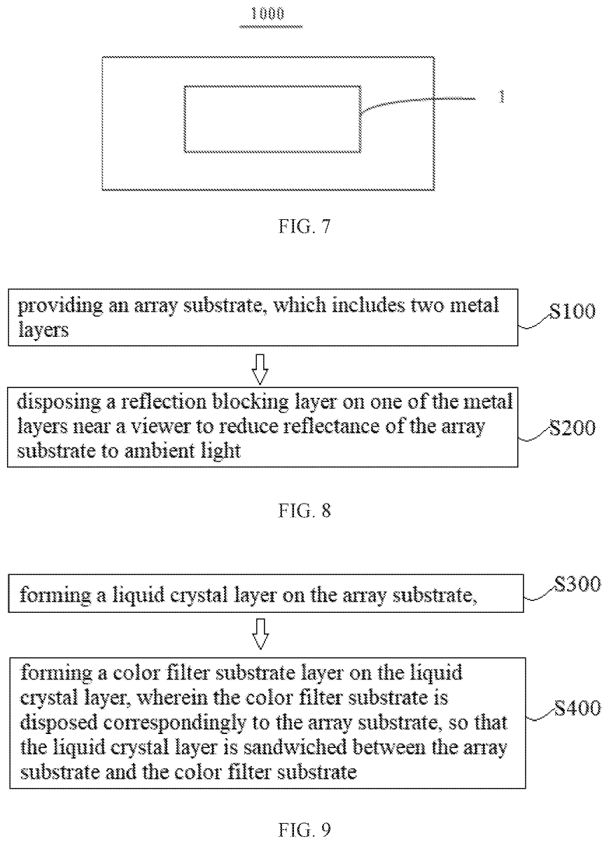

Please refer to FIG. 7, which is a schematic structural diagram of a display device according to an embodiment of the present application. The display device 1000 includes the display panel 1. The display device 1000 includes a fixed display device and a mobile display device. The fixed display device includes, but is not limited to, a television, a desktop display, and the like, especially a fixed display device with a narrow bezel or no bezel. The mobile display device includes, but is not limited to, a mobile phone, a tablet computer, a smart watch, VR glasses, and the like.

In order to solve the above technical problem, the present invention provides a method of manufacturing a display panel.

Please refer to FIG. 8, which is a flowchart of a method of manufacturing a display panel according to an embodiment of the present application. The method includes the following steps:

S100. providing an array substrate, which includes two metal layers.

In the step S100, the method of providing an array substrate includes: providing a support substrate; and sequentially forming a first metal layer, a first insulating layer, an active layer, and a second metal layer on the support substrate. In addition, the method of manufacturing each layer includes spin-coating, vacuum-evaporation coating, or inkjet-printing; and different layers can be prepared by the same or different methods.

Further, the first metal layer may be a gate layer; and the second metal layer is a source/drain layer. The active layer may be a polysilicon layer, and the first insulating layer may be made of an organic material or an inorganic material. When the insulating material is an inorganic material, it may be silicon nitride, silicon oxide, or a composite thereof. When the insulating material is made of an organic material, it may be a resin series insulating film, an acrylic series insulating film, or the like.

S200. disposing a reflection blocking layer on one of the metal layers near a viewer to reduce reflectance of the array substrate to ambient light.

In the step S200, disposing a reflection blocking layer on one of the metal layers near a viewer can reduce the reflection of the metal layer to ambient light and provide a better viewing experience. When the array substrate of the display panel is close to the viewer, the method further includes: disposing the reflection blocking layer between the support substrate and the first metal layer. When the color filter substrate of the display panel is close to the viewer, the method further includes: disposing the reflection blocking layer on the second metal layer.

Further, please refer to FIG. 9, which is a flowchart of a method of manufacturing a display panel according to another embodiment of the present application. The method includes the following steps:

S300. forming a liquid crystal layer on the array substrate,

S400. forming a color filter substrate layer on the liquid crystal layer, wherein the color filter substrate is disposed correspondingly to the array substrate, so that the liquid crystal layer is sandwiched between the array substrate and the color filter substrate.

In this embodiment, the display panel drives the liquid crystal sandwiched between the array substrate and the color filter substrate by applying a voltage to the array substrate and the color filter substrate, to achieve the effect of displaying a screen.

The technical benefits and technical details of the embodiments have been explained in detail in the foregoing, and not repeated herein for brevity.

In summary, the present application covers a metal layer that strongly reflects ambient light with a reflection blocking layer, which can effectively reduce a reflection of the metal layer to ambient light in a viewing angle of a viewer, thereby improving display contrast, thus beneficial to improving a viewing experience of the viewer.

The above is only an embodiment of the present invention, and thus does not limit the patent scope of the present invention. Any equivalent structure or equivalent process transformation made by using the description and drawings of the present invention, or directly or indirectly applied to other related technologies fields, all of which are included in the patent protection scope of the present invention.

What is claimed is:

1. A display panel, comprising:
a color filter substrate;
an array substrate disposed correspondingly to the color filter substrate and comprising two metal layers; and
a liquid crystal layer sandwiched between the color filter substrate and the array substrate,
wherein a reflection blocking layer is disposed on one of the metal layers near a viewer, to reduce a reflectance of the array substrate to ambient light.

2. The display panel according to claim 1, wherein the array substrate comprises:
a support substrate; and
a first metal layer, a first insulating layer, an active layer, and a second metal layer sequentially disposed on the support substrate,
wherein the reflection blocking layer is disposed between the support substrate and the first metal layer.

3. The display panel according to claim 2, wherein the reflection blocking layer is further disposed between the second metal layer and the active layer.

4. The display panel according to claim 2, wherein the display panel further comprises:
a first intermediate layer disposed between the reflection blocking layer and the first metal layer to improve adhesion between the reflection blocking layer and the first metal layer; and
a second intermediate layer disposed between the reflection blocking layer and the second metal layer to improve adhesion between the reflection blocking layer and the second metal layer.

5. The display panel according to claim 1, wherein the array substrate comprises:
a support substrate; and
a first metal layer, a first insulating layer, an active layer, and a second metal layer sequentially disposed on the support substrate,
wherein the reflection blocking layer is disposed on the second metal layer.

6. The display panel according to claim 5, wherein the reflection blocking layer is further disposed on the first metal layer.

7. The display panel according to claim 1, wherein the reflection blocking layer comprises:
a resin and a dye, the dye comprising a perylene dimer dye or a mixture of the perylene dimer dye and carbon black,
wherein the perylene dimer has a structural formula as follows: 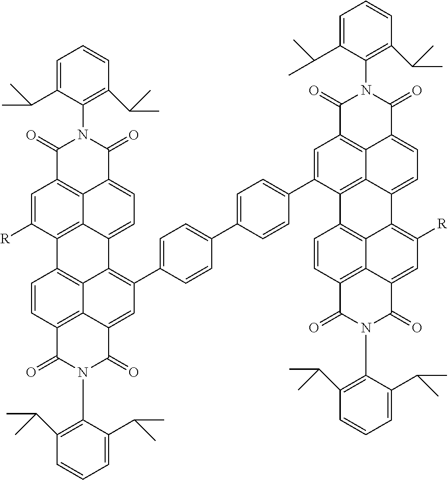
wherein R comprises at least one of the following chemical structures:

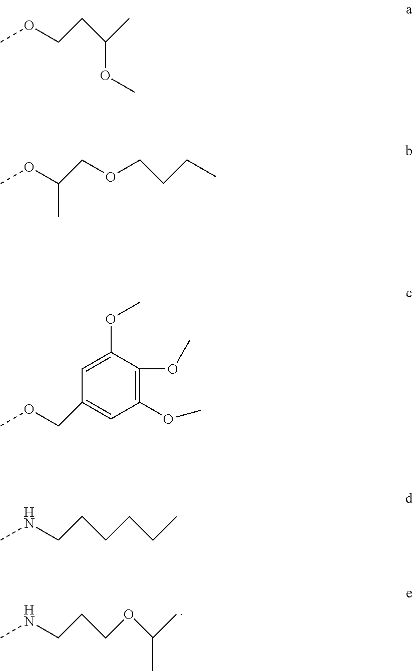

8. The display panel according to claim 7, wherein R comprises at least one group of a and d, a and e, b and d, c and d, and c and e.

9. A display device, comprising a display panel; the display panel comprising:
a color filter substrate;
an array substrate disposed correspondingly to the color filter substrate and comprising two metal layers; and
a liquid crystal layer sandwiched between the color filter substrate and the array substrate,
wherein a reflection blocking layer is disposed on one of the metal layers near a viewer, to reduce a reflectance of the array substrate to ambient light.

10. The display device according to claim 9, wherein the array substrate comprises:
a support substrate; and
a first metal layer, a first insulating layer, an active layer, and a second metal layer sequentially disposed on the support substrate,
wherein the reflection blocking layer is disposed between the support substrate and the first metal layer.

11. The display device according to claim 10, wherein the reflection blocking layer is further disposed between the second metal layer and the active layer.

12. The display device according to claim 10, wherein the display panel further comprises:
a first intermediate layer disposed between the reflection blocking layer and the first metal layer to improve adhesion between the reflection blocking layer and the first metal layer; and
a second intermediate layer disposed between the reflection blocking layer and the second metal layer to improve adhesion between the reflection blocking layer and the second metal layer.

13. The display device according to claim 9, wherein the array substrate comprises:
a support substrate; and
a first metal layer, a first insulating layer, an active layer, and a second metal layer sequentially disposed on the support substrate,
wherein the reflection blocking layer is disposed on the second metal layer.

14. The display device according to claim 13, wherein the reflection blocking layer is further disposed on the first metal layer.

15. The display device according to claim 9, wherein the reflection blocking layer comprises:
a resin and a dye, the dye comprising a perylene dimer dye or a mixture of the perylene dimer dye and carbon black;
wherein the perylene dimer has a structural formula as follows: 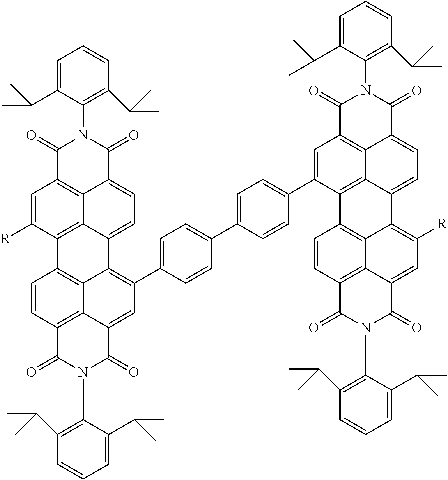
wherein R comprises at least one of the following chemical structures:

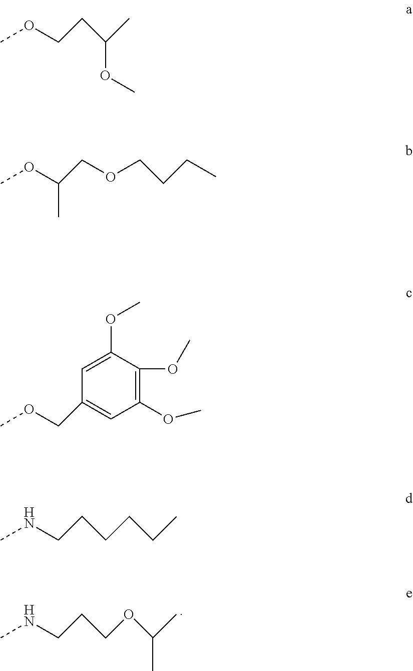

16. The display device according to claim 15, wherein R comprises at least one group of a and d, a and e, b and d, c and d, and c and e.

17. A method of manufacturing a display panel, comprising:
providing an array substrate, which comprises two metal layers; and
disposing a reflection blocking layer on one of the metal layers near a viewer to reduce reflectance of the array substrate to ambient light.
